(19) United States
(12) Patent Application Publication
(10) Pub. No.: US 2026/0239927 A1
(43) Pub. Date: Aug. 13, 2026

(54) Method for Measuring Semiconductor Device, System for Measuring Semiconductor Device, and Display Apparatus

(71) Applicant: Hitachi High-Tech Corporation, Minato-ku, Tokyo (JP)

(72) Inventors: Miki AOYAGI, Tokyo (JP); Toshimasa KAMEDA, Tokyo (JP); Maki KIMURA, Tokyo (JP); Takeshi KATO, Tokyo (JP); Satoshi SAKAI, Tokyo (JP)

(21) Appl. No.: 19/153,369

(22) PCT Filed: Mar. 1, 2023
(86) PCT No.: PCT/JP2023/007502

§ 371 Date: Aug. 4, 2025

(51) Int. Cl. H10P 74/20; G01N 23/04; H10P 50/00; H10P 72/00

(52) U.S. Cl. CPC H10P 74/203; G01N 23/04; H10P 50/71; H10P 72/0616; G01N 2223/102; G01N 2223/6116

(57) ABSTRACT

This method for measuring a semiconductor device includes: preparing a semiconductor device 600 which includes a first structure 611 produced by a first manufacturing step, and a second structure 604 which is provided under the first structure 611 and is produced by a second manufacturing step performed after the first manufacturing step; removing the first structure 611 of the semiconductor device 600 by chemical reaction; irradiating the semiconductor device 600 from which the first structure 611 has been removed with a charged particle beam from above; and measuring a feature amount (amount of recess) of the second structure 604 using information acquired by the irradiation with the charged particle beam.

### TECHNICAL FIELD

The present disclosure relates to a method for measuring a semiconductor device, a system for measuring a semiconductor device and a display apparatus.

### BACKGROUND ART

In recent years, a semiconductor device of a GAA (Gate All Around) structure in which the entire circumference of a wire-shaped or sheet-shaped channel is covered with a gate is becoming mainstream (Refer to Patent Literature 1, for example). The GAA structure is formed by, after a stacked structure of a single-crystal silicon germanium (SiGe) layer and a single-crystal silicon (Si) layer is formed over a single-crystal silicon (Si) substrate, retreating the SiGe layer by etching (Refer to FIG. 4A, FIG. 4B, Paragraph 0022 of Patent Literature 1, and the like).

It has become especially important to monitor an amount of retreat (amount of recess) of a SiGe layer in performance evaluation for semiconductor devices of a GAA structure.

### CITATION LIST

### Patent Literature

Patent Literature 1: Japanese Unexamined Patent Application Publication No. 2022-027614

### SUMMARY OF INVENTION

### Technical Problem

Patent Literature 1 (Paragraph 0018) describes “A device further includes a gate stacked body formed over respective fins of a P-type device and an N-type device.” Patent Literature 1 (Paragraph 0019) further describes “In some embodiments, a gate stacked body includes a dielectric layer and an electrode layer. The gata stacked body can further one or more hard mask layers.”

Meanwhile, CD-SEM (Cristal Dimension-Scanning Electron Microscope) generally used to measure a semiconductor device observes and measures a sample from above; therefore, an amount of recess of a SiGe layer cannot be directly observed or measured because of such an upper structure like a gate stacked body as mentioned above.

It is an object of the present disclosure to provide a method and a measurement system for a semiconductor device and a display apparatus in which a feature amount of a lower structure that cannot be directly observed or measured because of an upper structure.

### Solution to Problem

A method for measuring a semiconductor device according to the present disclosure includes: preparing a semiconductor device having a first structure produced by a first manufacturing step and a second structure, provided under the first structure, produced by a second manufacturing step performed after the first manufacturing step; removing the first structure of the semiconductor device by chemical reaction; and applying a charged particle beam from above the semiconductor device with the first structure removed and using information obtained by the irradiation with the charged particle beam to measure a feature amount of the second structure.

A measurement system according to the present disclosure includes: a processing apparatus that processes a semiconductor device having a first structure produced by a first manufacturing step and a second structure, provided under the first structure, produced by a second manufacturing step performed after the first manufacturing step that removes the first structure of the semiconductor device by chemical reaction; and a measurement apparatus that applies a charged particle beam from above the semiconductor device with the first structure removed and uses information obtained by the irradiation with the charged particle beam to measure a feature amount of the second structure.

A display apparatus according to the present disclosure is a display apparatus capable of communicating with a measurement apparatus, the measurement apparatus measuring a feature amount of a second structure of a semiconductor device that has a first structure produced by a first manufacturing step and the second structure, provided under the first structure, produced by a second manufacturing step performed after the first manufacturing step and has the first structure removed by chemical reaction; and a measurement position on a wafer or a chip for which the measurement apparatus has measured a feature amount of the second structure is plotted and a map image containing a feature amount in the measurement position is displayed.

### Advantageous Effects of Invention

According to the present disclosure, a feature amount of a lower structure that cannot be directly observed or measured because of an upper structure can be measured.

Other problems and novel features will be apparent from the description of the present specification and the accompanying drawings.

### BRIEF DESCRIPTION OF DRAWINGS

FIG. 1 is a drawing illustrating an example of a measurement system 1.

FIG. 2 is a block diagram illustrating a hardware configuration of a host computer 100.

FIG. 3 is a drawing illustrating an example of such a scanning electron microscope (measurement apparatus 103) as CD-SEM.

FIG. 4 is a block diagram illustrating a hardware configuration of a display apparatus 400.

FIG. 5 is a flowchart showing a method for manufacturing a semiconductor device containing a GAA structure and a method for removing an upper structure performed before measurement of a semiconductor device.

FIG. 6 is a drawing illustrating change in a section of a product in a manufacturing process for a semiconductor device.

FIG. 7 is a drawing illustrating change in a section of a product in a manufacturing process for a semiconductor device.

FIG. 8 is a drawing illustrating change in a section of a product in a manufacturing process for a semiconductor device.

FIG. 9 is a drawing explaining the details of an amount of recess.

FIG. 10 is a schematic diagram of an electron microscope image 1000 of a Si/SiGe stacked layer 604.

FIG. 11 is a flowchart of a comparison operation for a width of a spacer and an amount of recess.

FIG. 12 is a drawing illustrating an example of a GUI screen displaying a measured amount of recess and an operation result related to an amount of recess.

FIG. 13 is a drawing illustrating another example of a GUI screen displaying a measured amount of recess and an operation result related to an amount of recess.

FIG. 14 is a drawing illustrating an example of a GUI screen displaying a measurement result over a wafer map.

FIG. 15 is a drawing illustrating an example of a GUI screen chronologically displaying wafer maps of different measurement targets.

### DESCRIPTION OF EMBODIMENTS

In the following description, an embodiment will be divided into a plurality of sections or embodiments if necessary for convenience's sake; however, these sections and embodiments are not irrelevant to each other and one is a modification, details, a supplementary explanation, or the like of part or all of another unless explicitly specified.

When a number of elements or the like (including a number of pieces, a numerical value, an amount, a range, and the like) is referred to in the following description of embodiments, the specific number is not restrictive and any number higher or lower than the specific number is also acceptable unless explicitly specified or the specific number is theoretically and clearly restrictive.

In the following description of embodiments, a component (including an elementary step and the like) thereof is not indispensable unless explicitly specified or the component is theoretically and clearly indispensable, needless to add.

Similarly, when a shape, a positional relation, or the like of a component or the like is referred to in the following description of embodiments, the shape, positional relation, or the like includes those substantially close to the shape or the like or similar thereto unless explicitly specified or they are not clearly close or similar to the shape or the like. This is also the case with the above-mentioned numeric value and range.

In all the drawings explaining embodiments, an identical member will be marked with an identical reference sign in principle and a repetitive description thereof will be omitted.

### Measurement System 1

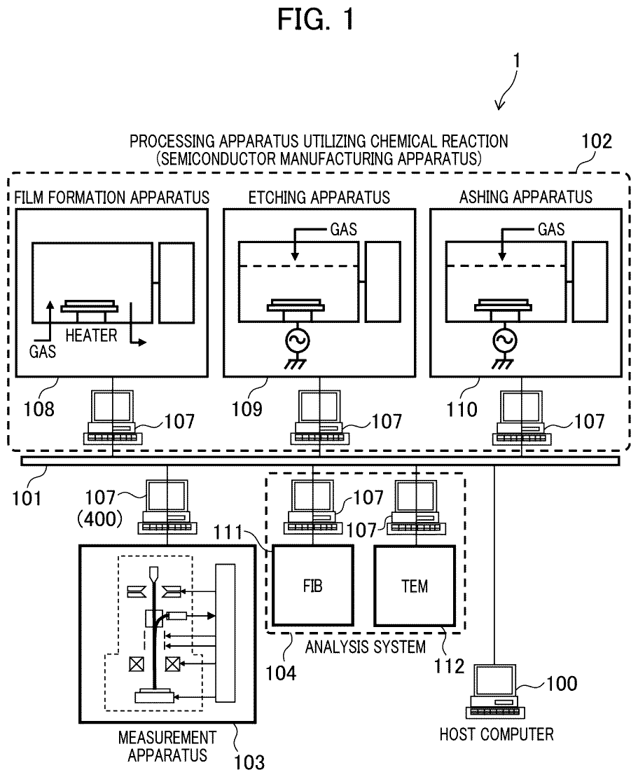

FIG. 1 is a drawing illustrating an example of a measurement system 1. The measurement system 1 shown in FIG. 1 as an example is used to correctly evaluate an amount of recess of, for example, a SiGe layer (lower structure) of a GAA (Gate All Around) structure. The measurement system 1 mainly includes a host computer 100, a semiconductor manufacturing apparatus 102, a measurement apparatus 103, and an analysis system 104. The host computer 100 is so connected as to be capable of communicating with the semiconductor manufacturing apparatus 102, the measurement apparatus 103, and the analysis system 104 via a network 101.

### Host Computer 100

The host computer 100 is so configured that the host computer causes each apparatus to operate through a computer system 107 provided in each connected apparatus and can process information obtained at each apparatus. In the measurement system 1 shown in FIG. 1 as an example, the computer system 107 that exercises control and the like of each apparatus is provided separately from the host computer 100; however, the host computer 100 and at least one computer system 107 may be integrated with each other. Each apparatus is provided separately from the computer system 107 connected to each apparatus; however, an apparatus and the computer system 107 provided in the apparatus may be integrated with each other.

### Hardware Configuration of Host Computer 100

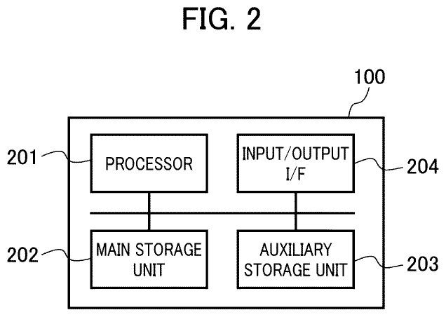

FIG. 2 is a block diagram illustrating a hardware configuration of the host computer 100. The host computer 100 includes a processor 201, a main storage unit 202, an auxiliary storage unit 203, and input/output I/F (InterFace) 204. The processor 201 is a central processing unit that performs various arithmetic operations. The processor 201 is, for example, a CPU (Central Processing Unit), a DSP (Digital Signal Processor), an ASIC (Application Specific Integrated Circuit), or the like. The main storage unit 202 stores a program executed by the processor 201, data required to execute the program, and the like. The main storage unit 202 is, for example, RAM (Random Access Memory), a flash memory, or the like. The auxiliary storage unit 203 stores various programs and varied data. The auxiliary storage unit 203 stores, for example, OS (Operating System), various programs, varied data required to execute the programs, and the like. The auxiliary storage unit 203 is, for example, a solid-state drive (SSD) apparatus, a hard disk drive (HDD) apparatus, or the like. The input/output I/F 204 is a device controller communicatively connected with a keyboard, a mouse, a display, or the like, a network controller communicatively connected with a network, or the like.

The processor 201 expands, in an executable manner, a program (for example, control software for controlling operation of each apparatus of a processing apparatus 102 and the measurement apparatus 103) in a work area in the main storage unit 202. For example, the processor 201 executes control software expanded in the main storage unit 202 and controls execution of upper structure removal processing by the processing apparatus 102.

Here, a description has been given to a hardware configuration of the host computer 100; however, the computer systems 107 also have the same hardware configuration as that of the host computer 100. One or more computer systems 107 may execute the above-mentioned control software to control execution of upper structure removal processing by the processing apparatus 102.

### Processing Apparatus Utilizing Chemical Reaction (Semiconductor Manufacturing Apparatus 102)

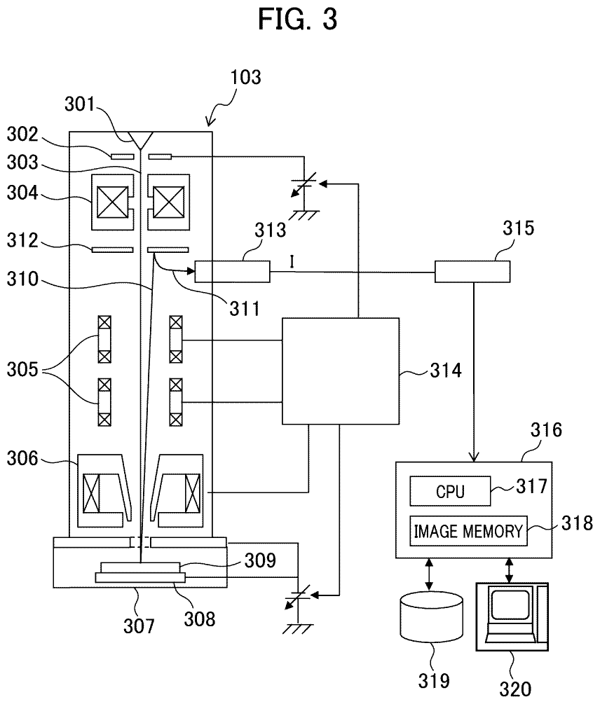

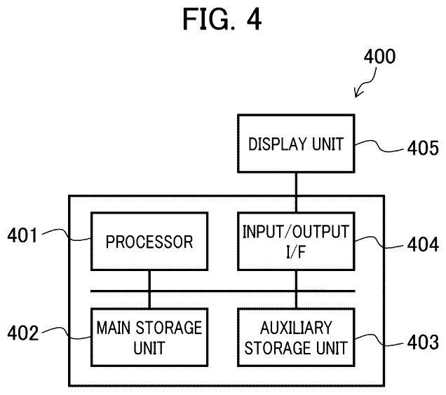

The measurement system 1 shown in FIG. 1 as an example includes an apparatus (processing apparatus (semiconductor manufacturing apparatus 102) utilizing chemical reaction) for removing an upper structure (for example, a dummy gate stacked body (FIG. 3A, FIG. 3B, and the like in Patent Literature 1, for example)) that prevents arrival of such a charged particle beam as an electron beam or light to correctly evaluate an amount of recess of a SiGe layer of a GAA structure. The dummy gate stacked boy as an example of an upper structure is a dummy gata stacked body removed by subsequent processing and replaced with a final gata stacked body.

Recess of a SiGe layer (lower structure) of a GAA structure is formed, after an upper structure is formed by a first manufacturing step, by etching or the like in a second manufacturing step. For this reason, when recess of a SiGe layer is formed, an upper structure that prevents arrival of a charged particle beam has been already formed above the SiGe layer. Therefore, it is desirable to remove the upper structure before a measurement or an inspection is performed to evaluate recess of a lower structure located beneath. In the present embodiment, a semiconductor device with an upper structure removed is taken as a measurement target; however, a semiconductor device with an upper structure remaining may be taken as a measurement target.

As a processing apparatus (semiconductor manufacturing apparatus 102) utilizing chemical reaction, the measurement system 1 shown in FIG. 1 as an example includes a film formation apparatus 108, an etching apparatus 109, and an ashing apparatus 110.

### Film Formation Apparatus 108

The film formation apparatus 108 is used to fill a mask layer. The film formation apparatus 108 is, for example, an ALD (Atomic Layer Deposition) apparatus, a CVD (Chemical Vapor Deposition) apparatus, or the like that can form a mask layer on a substrate. The computer system 107 connected to the film formation apparatus 108 exercises control so that the film formation apparatus 108 performs film formation processing in accordance with a recipe (operation program) registered in advance.

### Etching Apparatus 109

The etching apparatus 109 is an apparatus that subjects a shape of a thin film to chemical corrosion or etching using chemical reaction of liquid chemical, reactant gas, or ion. In the present embodiment, after a mask layer is filled, the etching apparatus 109 is used to remove an upper structure that prevents arrival of an electron beam at a Si/SiGe stacked layer. Like the computer system 107 connected to the film formation apparatus 108, the computer system 107 connected to the etching apparatus 109 also exercises control so that the etching apparatus 109 performs removal processing in accordance with a recipe (operation program) registered in advance.

### Ashing Apparatus 110

The ashing apparatus 110 is an apparatus for stripping resist or the like and removes resist or the like as gas, for example, by causing plasmolyzed gas and the resist to chemically react with each other. In the present embodiment, the ashing apparatus is used mainly to remove a mask layer. Like the computer system 107 connected to the film formation apparatus 108, the computer system 107 connected to the ashing apparatus 110 also exercises control so that the ashing apparatus 110 performs removal processing in accordance with a recipe (operation program) registered in advance.

### Measurement Apparatus 103

The measurement system 1 shown in FIG. 1 as an example further includes the measurement apparatus 103. The measurement apparatus 103 is, for example, CD-SEM (Critical Dimension Scanning Electron Microscope) and, after removal of an upper structure on a Si/SiGe stacked layer, measures an amount of recess or the like of a SiGe layer based on application of a beam to the Si/SiGe stacked layer. A definition of an amount of recess will be described later.

FIG. 3 is a drawing illustrating an example of such a scanning electron microscope (measurement apparatus 103) as CD-SEM. An electron beam 303 (charged particle beam 31) extracted from an electron source 301 by an extraction electrode 302 is accelerated by an acceleration electrode, not shown. The accelerated electron beam 303 is squeezed by a condenser lens 304, a type of a convergence lens, and then deflected by a scanning deflector 305. As a result, the electron beam 303 one-dimensionally or two-dimensionally scans on a sample 309 (for example, a semiconductor device). The electron beam 303 incident on the sample 309 is decelerated by a decelerating electric field formed by applying a negative voltage to an electrode built in a sampling stage 308 and is further converged by a lens action of an objective lens 306 and applied to the surface of the sample 309. The interior of a sample chamber 307 is kept in vacuum.

Electrons 310 (secondary electrons, backscattered electrons, or the like) are emitted from an irradiation point on the sample 309. The emitted electrons 310 are accelerated toward the electron source 301 by accelerating action based on a negative voltage applied to the above-mentioned electrode built in the sampling stage 308.

The accelerated electrons 310 collide with a conversion electrode 312 and produce secondary electrons 311. The secondary electrons 311 emitted from the conversion electrode 312 are detected by a detector 313 and an output I of the detector 313 varies depending on an amount of captured secondary electrons. According to this variation in the output I, a brightness of an image varies. To form a two-dimensional image, for example, a deflection signal to the scanning deflector 305 and the output I of the detector 313 are synchronized with each other to form an image of a scanning region.

With respect to the CD-SEM (measurement apparatus 103) shown in FIG. 3 as an example, a case where electrons 310 emitted from the sample 309 are once converted into secondary electrons 311 at the conversion electrode 312 and detected; however, the present disclosure is not limited to this configuration, needless to add, for example, a configuration in which an electron multiplier tube or a detection surface of a detector is placed on a trajectory of the accelerated electrons may be adopted. A control apparatus 314 supplies control signals required for each optical element of the above-mentioned CD-SEM in accordance with an operation program, called imaging recipe, for controlling the CD-SEM.

Subsequently, a signal detected at the detector 313 is converted into a digital signal by an A/D converter 315 and is sent to an image processing unit 316. The image processing unit 316 integrates signals obtained by a plurality of times of scanning on a frame-by-frame basis and thereby generates an integrated image.

Here, an image obtained by one time of scanning in a scanning region is designated as an image of one frame. To integrate images of eight frames, for example, signals obtained by eight times of two-dimensional scanning are subjected to arithmetic mean processing on a pixel-by-pixel basis and thereby generates an integrated image. An identical scanning region may be scanned a plurality of times and a plurality of images of one frame may be generated and stored for each scanning.

Further, the image processing unit 316 includes: an image memory 318 that is an image storing medium for temporarily storing digital images; and CPU 317 calculates a feature amount (dimension values of a width of a line and a hole, roughness indication values, indication values indicating a pattern shape, an area value of a pattern, a pixel position that provides an edge position, and the like) from an image stored in the image memory 318. In the present embodiment, for example, the CPU 317 calculates an amount of recess of a SiGe layer of a GAA structure of a semiconductor device.

Further, the measurement apparatus 103 includes a storing medium 319 that stores measurement values of each pattern, a luminance value of each pixel, and the like. Overall control is so configured that operation of a required apparatus, confirmation of a detection result, and the like performed by a workstation 320 are implemented by a graphical user interface (hereafter, referred to as GUI). The image memory 318 is so configured that an output signal (a signal in proportion to a quantity of electrons emitted from a sample) of the detector 313 is stored at a corresponding address (x, y) in the memory in synchronization with a scanning signal supplied to the scanning deflector 305. The image processing unit 316 also functions as a processing unit that generates a line profile from luminance values stored in the memory, determines an edge position using a threshold method or the like, and measures a distance between edges.

Instead of the workstation 320 or the image processing unit 316, the computer system 107 or the host computer 100 shown in FIG. 1 as an example may be used to perform required control and arithmetic processing.

### Display Apparatus 400

A description will be given to the display apparatus 400 that displays a measurement result of the measurement apparatus 103. The display apparatus 400 is, for example, the computer system 107 connected to the measurement apparatus 103.

Like the hardware configuration of the above-mentioned host computer 100, the display apparatus 400 includes a processor 401, a main storage unit 402, an auxiliary storage unit 403, and an input/output I/F 404. Since these elements are identical with those of the host computer 100, a detailed description thereof will be omitted.

The display apparatus 400 further includes such a display unit 405 as a liquid crystal display apparatus or an organic EL display apparatus. A UI screen displayed in the display unit 405 will be described later.

### Analysis System 104

The measurement system 1 shown in FIG. 1 as an example includes the analysis system 104. The analysis system 104 includes an FIB (Focused Ion Beam) apparatus 111 and TEM (Transmission Electron Microscope) 112. The FIB apparatus 111 is an apparatus that processes a sample by irradiating the sample with an ion beam emitted from a liquid metal ion source of gallium or the like. A spot of a sample irradiated with a beam is sputtered and desired processing such as drilling can be performed there. The TEM 112 is an apparatus that applies an electron beam to a thinned sample to form an image of electrons that permeate the sample and thereby generates an enlarged image of the sample. For example, based on positional information inputted from the host computer 100 or the computer system 107, the FIB apparatus 111 processes a section of a sample in a desired position and further processes an exposed sectional portion to thin the portion. The TEM 112 is used to measure a thinned sample and measure, for example, an amount of recess of a SiGe layer based on an observation image of the sample.

### Method for Manufacturing Semiconductor Device

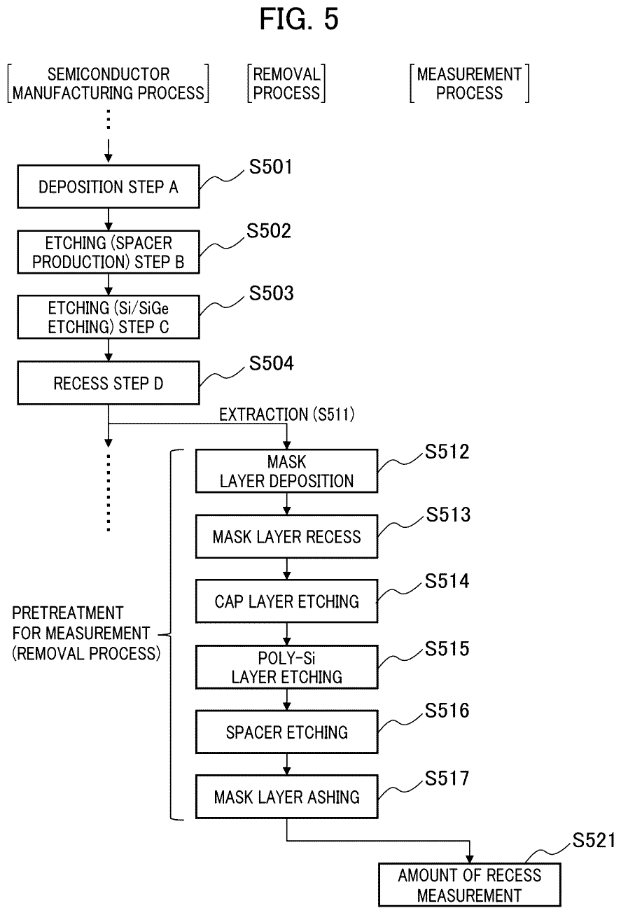

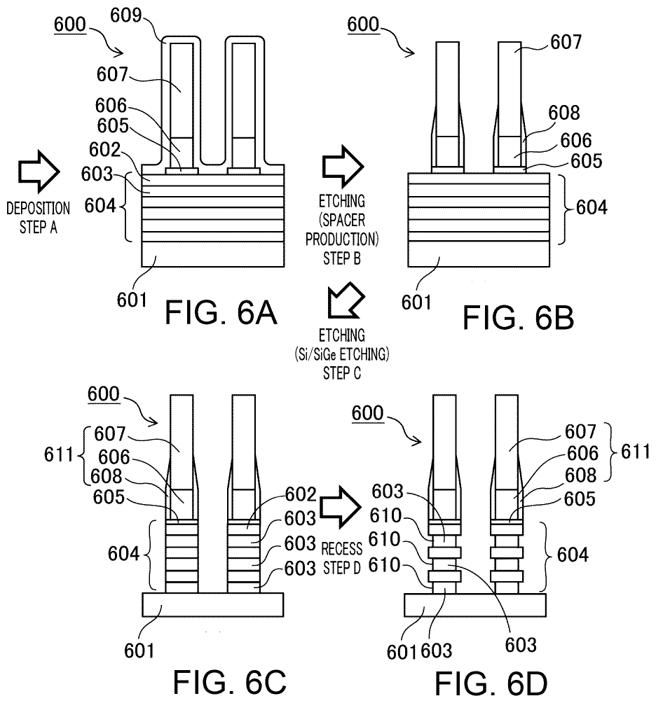

FIG. 5 is a flowchart showing a method for manufacturing a semiconductor device containing a GAA structure and a method for removing an upper structure performed before measurement of a semiconductor device. FIGS. 6 to 8 are drawings illustrating change in a section of a product in a manufacturing process for a semiconductor device.

First, a description will be given to a method for manufacturing a Fin-shaped semiconductor device with reference to FIG. 5 and FIG. 6.

### Deposition Step A

First, a semiconductor device 600 is prepared which semiconductor device includes: an impurity region 601; a Si/SiGe stacked layer 604 which is formed over the impurity region 601 and in which a Si layer 602 and a SiGe layer 603 are alternately stacked; a gate insulating film 605 formed over the Si/SiGe stacked layer 604; a Poly-Si layer 606 (polysilicon layer) formed over the gate insulating film 605; and a cap layer 607 (SiN) formed over the Poly-Si layer 606. Then a SiOCN layer 609 for forming a spacer 608, described later, over the surface of the semiconductor device 600 is deposited (S501 in FIG. 5, (a) of FIG. 6).

### Etching Step B

Subsequently, the semiconductor device 600 with the SiOCN layer 609 deposited over the surface thereof is etched to form the spacer 608 (S502 in FIG. 5, (b) of FIG. 6).

### Etching Step C

After the formation of the spacer 608, the Si/SiGe stacked layer 604 is etched to produce such a Fin-shaped structure (second structure) as shown in FIG. 6(c) (S503 in FIG. 5, (c) of FIG. 6).

### Recess Step D

After a side wall of the Si/SiGe stacked layer 604 (second structure) is exposed as shown in FIG. 6(c), the SiGe layer 603 is selectively etched to from recess 610 (S504 in FIG. 5, (d) of FIG. 6). FIG. 6(d) is a drawing illustrating a section of the Fin-shaped semiconductor device 600 obtained after the formation of the recess 610.

In a GAA transistor, determination of whether recess 610 is appropriately formed is important to confirm whether the transistor properly works as a semiconductor element. However, since the recess 610 is formed after an upper structure 611 (first structure) is formed, as shown in FIG. 6 as an example, the upper structure 611 hinders measurement based on beam irradiation. The upper structure 611 is, for example, a dummy gate stacked body and includes the Poly-Si layer 602, the cap later 607 formed over the Poly-Si layer 602, and the spacer 608 providing a side wall of the upper structure 611. Consequently, in relation to the embodiment described below, a description will be given to a removal method for removing the upper structure 611 as a pretreatment for measurement.

### Method for Removing Upper Structure 611

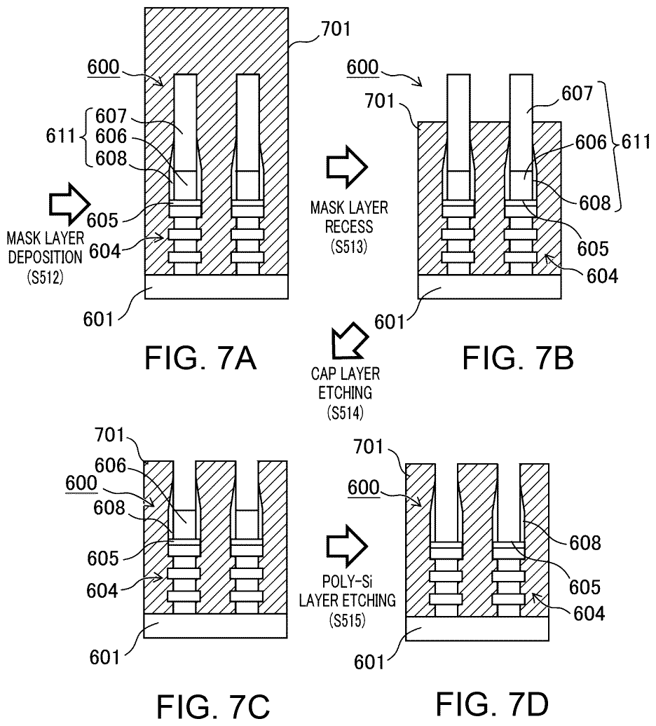

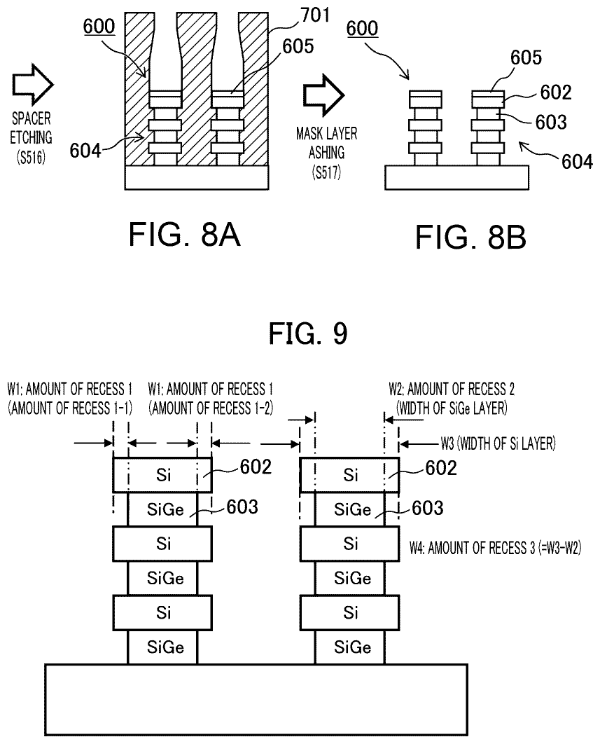

Subsequently, a description will be given to a method for removing the upper structure 611 (dummy gate stacked body: Poly-Si layer 606, cap layer 607, and spacer 608) of the Fin-shaped semiconductor device 600 with reference to FIG. 5, FIG. 7, and FIG. 8.

First, a semiconductor wafer as a measurement target is extracted from a semiconductor manufacturing process (S511).

### Deposition of Mask Layer

Then, using the film formation apparatus 108, a mask layer 701 is deposited over the semiconductor wafer (S512). FIG. 7(a) is a sectional view of the semiconductor device 600 observed after the deposition of the mask layer 701. The film formation apparatus 108 deposits the mask layer 701 in accordance with a film thickness condition set by the host computer 100 or the computer system 107 (computer or the like). To protect the Si/SiGe stacked layer 604 as well as the gate insulating film 605 in the etching or ashing step for removing the upper structure 611, this mask layer 701 is provided so as to cover at least a side face of the Si/SiGe stacked layer 604. For this reason, the mask layer is so formed that the surface thereof is located above at least the Si/SiGe stacked layer 604.

### Recess of Mask Layer

Subsequently, using the etching apparatus 109, the mask layer 701 is recessed (S513). FIG. 7(b) is a sectional view of the semiconductor device 600 with the mask layer 701 partly recessed. At S513, the mask layer 701 is recessed so that at least part of the cap layer 607 is exposed on condition that the surface of the mask layer 701 is positioned above the upper end of the spacer 608. This recess is performed on condition that Fin (Si/SiGe stacked layer 604) is hidden by the mask layer 701 at the time of the Poly-Si layer 606 removal, described later. Since the mask layer 701 may be retreated depending on selection of an etching rate at the time of side wall removal and the mask layer 701 may be retreated also at the time of the Poly-Si layer 606 removal, it is advisable to select an amount of recess with an amount of the retreat taken into account (so that the Fin is hidden even after the mask layer is retreated).

### Etching of Cap Layer

Subsequently, using the etching apparatus 109, the cap layer 607 is removed by etching (S514). FIG. 7(c) is a sectional view of the semiconductor device 600 observed after the removal of the cap layer 607. In a storing medium, not shown, built in the computer system 107 controlling the etching apparatus 109, an etching condition for removing the cap layer 607 is stored in advance.

### Etching of Poly-Si Layer

Subsequently, using the etching apparatus 109, the Poly-Si layer 606 is removed by etching (S515). FIG. 7(d) is a sectional view of the semiconductor device 600 observed after the removal of the Poly-Si layer 606. In a storing medium, not shown, built in the computer system 107 controlling the etching apparatus 109, an etching condition for removing the Poly-Si layer 606 is stored in advance.

### Etching of Spacer

Subsequently, to remove the remaining spacer 608, the spacer 608 is etched by the etching apparatus 109 (S516). FIG. 8(a) is a sectional view of the semiconductor device 600 observed after the removal of the spacer 608. When the spacer 608 is of such a SiN-based material as SiN or SiOCN, dry etching using a gas in which oxygen or hydrogen is contained in a CF gas or oxygen is contained in a CHF gas or wet etching using a heated phosphoric acid solution can be used.

### Ashing of Mask Layer

After the removal of the spacer 608, using the ashing apparatus 110, the mask layer 701 provided for the protection of the Si/SiGe stacked layer is removed by ashing (S517). As a result, a side wall of the Si/SiGe stacked layer 604 can be exposed. FIG. 8(b) is a sectional view of the semiconductor device 600 observed after the removal of the mask layer 701. When the mask layer 701 is resist or a carbon organic film, the mask layer 701 can be removed by performing ashing in an oxygen atmosphere at high temperature (for example, 300° C.).

The surface of the Si/SiGe stacked layer 604 is exposed by removal of the upper structure 611 (Poly-Si layer 606, cap layer 607, and spacer 608).

### Method for Measuring Semiconductor Device 600 (Amount of Recess of SiGe Layer 603)

In the present embodiment, the measurement apparatus 103 irradiates the Si/SiGe stacked layer 604 with the upper structure 611 removed with an electron beam to measure an amount of recess of the SiGe layer 603 (S521). In this measurement process (S521), an electron beam having energy at such a level that the electron beam can penetrate the Si layer 602 and the gate insulating film 605 is applied to the Si/SiGe stacked layer 604 and the electron beam is thereby caused to arrive at recess.

### Amount of Recess

A description will be given to the details of an amount of recess with reference to FIG. 9.

As shown in FIG. 9 as an example, a dimension W1 between one end of the Si layer 602 (Si nanosheet) and one end of the recessed SiGe layer 603 may be defined as an amount of recess (amount of recess 1). A dimension (amount of recess 1-1) between one end of the Si layer 602 (Si nanosheet) and one end of the recessed SiGe layer 603 and a dimension (amount of recess 1-2) between the other end of the Si layer 602 (Si nanosheet) and the other end of the recessed SiGe layer 603 may be managed as different amounts of recess.

Further, a width W2 of the SiGe layer 603 may be defined as an amount of recess (amount of recess 2).

Further, a difference W4 between a width of W3 of the Si layer 602 and a width W2 of the SiGe layer 603 may be defined as an amount of recess (amount of recess 3).

### Method for Measuring Amount of Recess

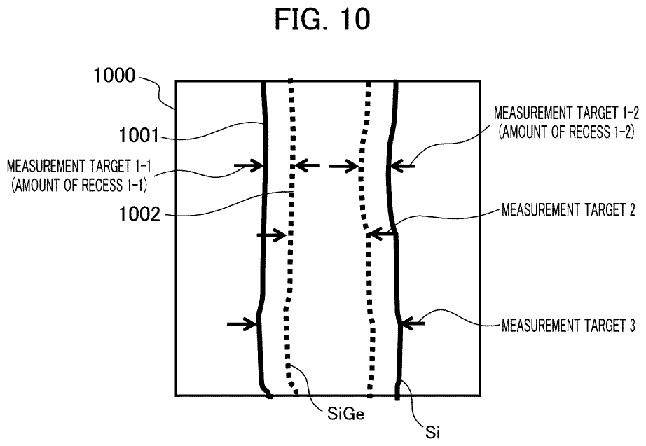

FIG. 10 is a schematic diagram of an electron microscope image 1000 of the Si/SiGe stacked layer 604. When incident electrons (primary electron beam) permeate the Si layer 602 and escape to the recess portion, secondary electrons are produced by the Si layer 602; therefore, the recess portion is brightly displayed as compared with a portion of the Si/SiGe stacked layer 604. Therefore, by generating a luminance signal profile in the X direction and measuring a width of a high-luminosity region, all the amounts of recess 1 to 3 or any one of the amounts of recess 1 to 3 can be measured.

Further, contour lines may be extracted between a high-luminosity region and a low-luminosity region by binarization or segmentation of the electron microscope image 1000 and a dimension between the contour lines may be measured. As mentioned above, a dimension between an edge 1001 of the Si layer and an edge 1002 of the SiGe layer, that is, one and the other of recess formed on the left and right of a fin may be taken as measurement targets (measurement target 1-1, measurement target 1-2) to evaluate an amount of recess 1-1 and an amount of recess 1-2.

Further, a width of the edge 1002 of the SiGe layer, that is, a width of the SiGe layer (width of the edge 1002) may be taken as a measurement target (measurement target 2) to evaluate an amount of recess 2 (etching condition).

Furthermore, a width of the edge 1001 of the Si layer may be taken as a measurement target (measurement target 3) and a difference from the above-mentioned measurement target 2 (width of the edge 1002 of the SiGe layer) may be determined to evaluate an amount of recess 3.

By measuring the semiconductor device 600 with the upper structure 611 removed by the above-mentioned removal process, amounts of recess 1 to 3 can be highly accurately measured.

### Method for Measuring Amount of Recess and Spacer Width

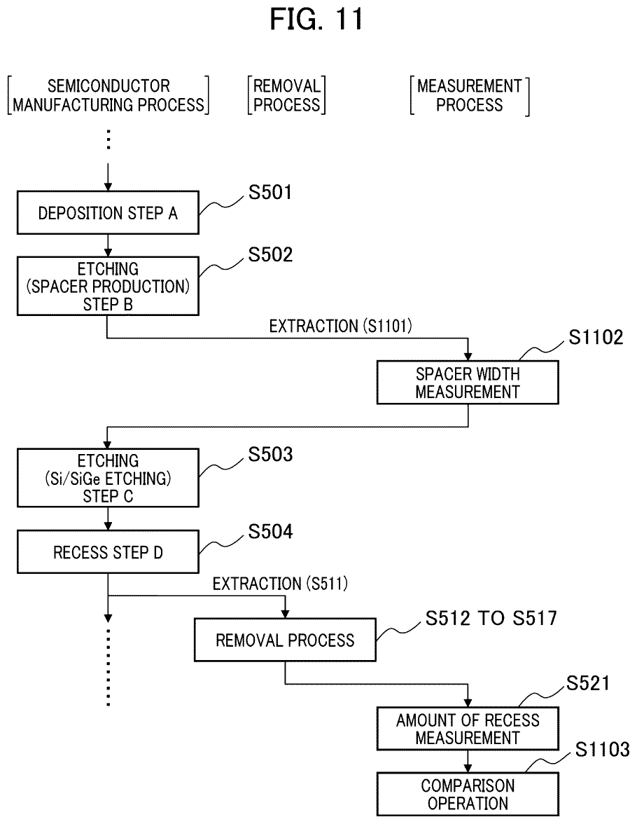

As shown in FIG. 5, an amount of recess of the SiGe layer 603 of the semiconductor device 600 with the upper structure 611 removed could be measured to evaluate only the amount of recess; instead, as shown in FIG. 11 below, an amount of recess and a feature amount of the upper structure 611 may be compared with each other to perform evaluation.

In the flowchart in FIG. 11, first, a semiconductor wafer having the semiconductor device 600((b) of FIG. 6) with the spacer 608 formed by the deposition step A at S501 and the etching step B at S502 is extracted from the semiconductor manufacturing process (S1101).

The measurement apparatus 103 irradiates the semiconductor device 600 with the spacer 608 formed with an electron beam to measure a width of the spacer 608 (S1102).

The semiconductor device 600 for which a width of the spacer 608 has been measured is returned to the semiconductor manufacturing process and the processing apparatus 102 manufactures the Fin-shaped semiconductor device 600 with the recess 610 formed by the etching step C at S503 and the recess step D at S504.

Subsequently, a semiconductor wafer as a measurement target is extracted from the semiconductor manufacturing process (S511) and by performing each step of S512 to S517, the processing apparatus 102 removes the upper structure 611 (Poly-Si layer 606, cap layer 607, and spacer 608).

The measurement apparatus 103 irradiates the Si/SiGe stacked layer 604 with the upper structure 611 removed with an electron beam to measure an amount of recess of the SiGe layer 603 (S521).

In the present flowchart, the measurement apparatus 103 subjects a width of the spacer 608 measured at S1102 and an amount of recess of the SiGe layer 603 measured at S521 to comparison operation (S1103).

### GUI Screen 1200 Displayed in Display Apparatus 400

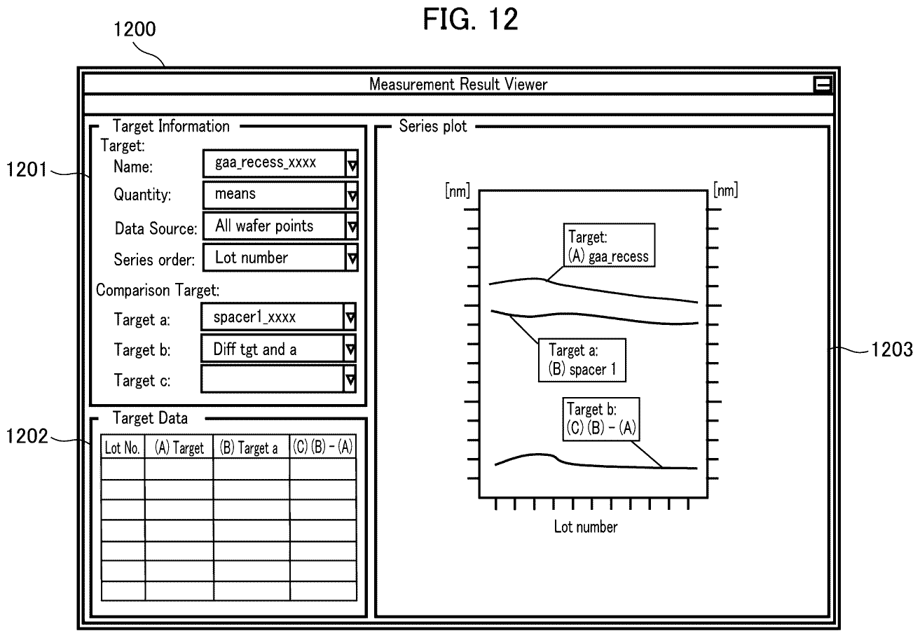

FIG. 12 is a drawing illustrating an example of the GUI (Graphical User Interface) screen displaying a measured amount of recess and an operation result related to an amount of recess. In the storing medium built in the display apparatus 400, computer software that displays such a GUI screen as shown in FIG. 12 as an example is stored and the display apparatus is so configured as to display a measurement result based on information set in the GUI screen.

The GUI screen 1200 shown in FIG. 12 as an example embraces: an input area 1201 for inputting measurement target information for which a measurement result is outputted; an output area 1202 for outputting a measurement result based on measurement target information inputted from the input area 1201; and a series plot area 1203 for displaying chronological transition of a measurement result.

The input area 1201 is provided with: an input field (“Name” in FIG. 12) for such a measurement target name as recess; a quantity selection field (“Quantity” in FIG. 12) in which an output format of such a measurement result as an average value, a sigma value, a range value, a maximum value, and a minimum value can be selected from a pulldown menu; a source selection field (“Data Source” in FIG. 12) for selecting a data source of a measurement result selected in the quantity selection field; and a series order selection field (“Series order” in FIG. 12) for inputting such information as a wafer number, a date, a lot number, and the like that define the horizontal axis of a graph displayed in the series plot area 1203.

The input area 1201 is further provided with an input field (“Comparison Target” in FIG. 12) for inputting a name of a target for comparison with a measurement target; when recess is taken as a target, for example, a spacer related to the formation of the recess and a type of the above-mentioned comparison operation can be inputted. A measurement result specified in this input area 1201 is read from a storing medium and is displayed in the output area 1202 together with additional information thereof.

A measurement result outputted to the output area 1202 is displayed in the series plot area 1203 as a graph. In the series plot area 1203, a graph is displayed in which graph the horizontal axis is defined based on information related to an order set in the above-mentioned series order selection field and the vertical axis is taken for a measurement result.

In the series plot area 1203, chronological variation in, for example, an amount of recess and any other part, a comparison operation result, and the like related to formation of recess is displayed; therefore, a user can visually determine variation in finish due to process fluctuation.

Especially, finish of recess and chronological variation in a portion probably influenced by finish of recess can be evaluated together; therefore, when an amount of recess varies, it can be swiftly confirmed whether the variation falls within an allowable range.

Especially, by displaying transition in difference calculation of an amount of recess and a spacer in graph as shown FIG. 12 as an example, if an amount of recess fluctuates, it is possible to correctly evaluate whether the fluctuation falls within an allowable range.

### GUI Screen 1300 Displayed in Display Apparatus 400

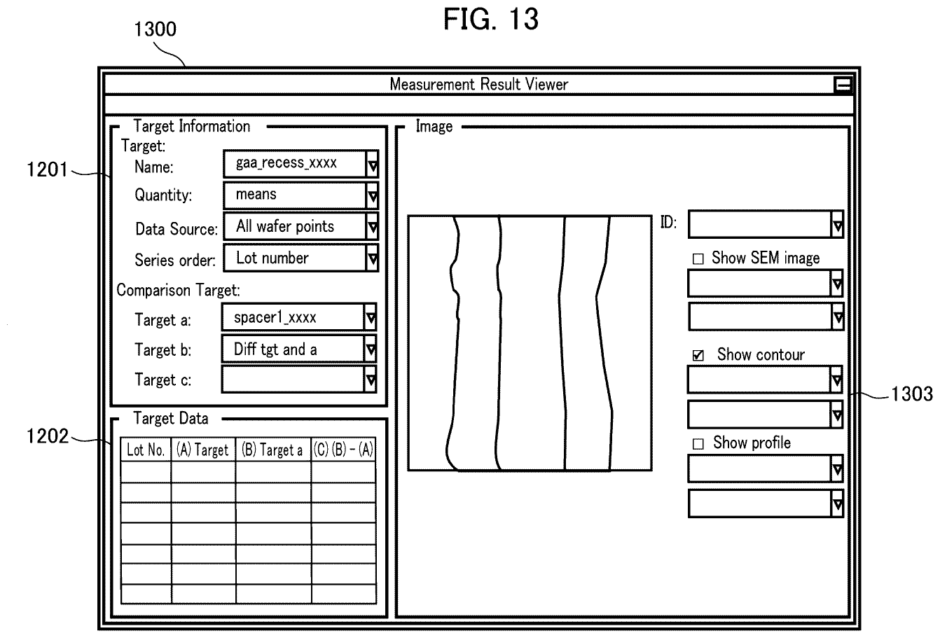

FIG. 13 is a drawing illustrating another example of a GUI screen displaying a measured amount of recess and an operation result related to an amount of recess. Based on a measurement result outputted by the measurement apparatus 103, a processor built in the display apparatus 400 or the like generates such a GUI screen 1300 as shown in FIG. 13 as an example in accordance with a program stored in a storing medium.

FIG. 12 and FIG. 13 are different from each other in that while the right field in FIG. 12 is the series plot area 1203, the right field in FIG. 13 is an image display area 1303. The image display area 1303 is provided for displaying at least one of an electron microscope image acquired, for example, at S1102 or S521 in FIG. 11, a contour line extracted from an electron microscope image, and a luminance profile indicating a luminance distribution in a specific direction of an electron microscope image.

Further, selection fields are provided for selecting a plurality of steps, image IDs, or the like so that contour line images or the like of a plurality of different manufacturing processes can be displayed in a superimposed manner. By selecting contour line images or the like obtained from different processes and displaying them in a superimposed manner based on the selection, a recess shape and a shape of a pattern having influence on the formation of recess can be visually and relatively evaluated.

### GUI Screen 1400 Displaying Measurement Result Over Wafer Map

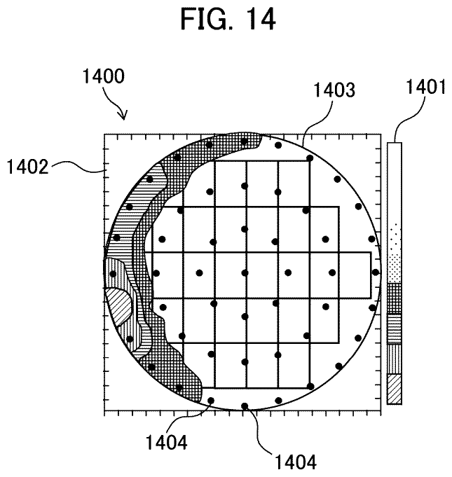

FIG. 14 is a drawing illustrating an example of a GUI screen displaying a measurement result over a wafer map. Based on a measurement result outputted by the measurement apparatus 103, a processor built in the display apparatus 400 or the like generates such a GUI screen 1400 as shown in FIG. 14 as an example in accordance with a program stored in a storing medium. Such a processing apparatus 102 utilizing chemical reaction as described above is capable of in-plane uniform processing on a wafer-by-wafer embracing a plurality of semiconductor devices or chip-by-chip basis. Unlike such partial cutting processing as in the FIB apparatus 111, processing (in the above-mentioned embodiment, pretreatment (removal process) for measurement of a GAA structure) of an entire target sample can be performed in a short time. That is, a target appearing under processing with high in-plane uniformity can be measured; therefore, extensive measurement targets can be measured on identical conditions. By making such an in-plane distribution display as shown in FIG. 14 as an example, an in-plane measurement target result appearing from pretreatment with high in-plane uniformity can be visualized; therefore, precise distribution evaluation can be made.

The GUI screen 1400 shown in FIG. 14 as an example embraces: a scale 1401 indicating a hue or shading corresponding to the magnitude of a measurement value; and a wafer map display window 1402. In the wafer map display window 1402, a cartesian coordinate system is defined and in the example in FIG. 14, the center of the cartesian coordinate system agrees with the center of the wafer map display window 1402.

An in-plane distribution diagram (map image) 1403 is displayed in the wafer map display window 1402. In the in-plane distribution diagram 1403, a plurality of measurement positions 1404 indicating positions in a wafer measured by the measurement apparatus 103 is plotted. Information displayed in the wafer map display window 1402 is stored in a storing medium of the display apparatus 400, the host computer 100, and the like. According to a measurement value of each portion obtained by interpolating measurement results at a plurality of measurement positions 1404, the interior of an in-plane distribution diagram 1403 is expressed by a hue or shading defined with the scale 1401.

By making such display, for example, a distribution of an amount of recess can be visually evaluated.

### GUI Screen 1500 of Chronologically Displayed Wafer Maps

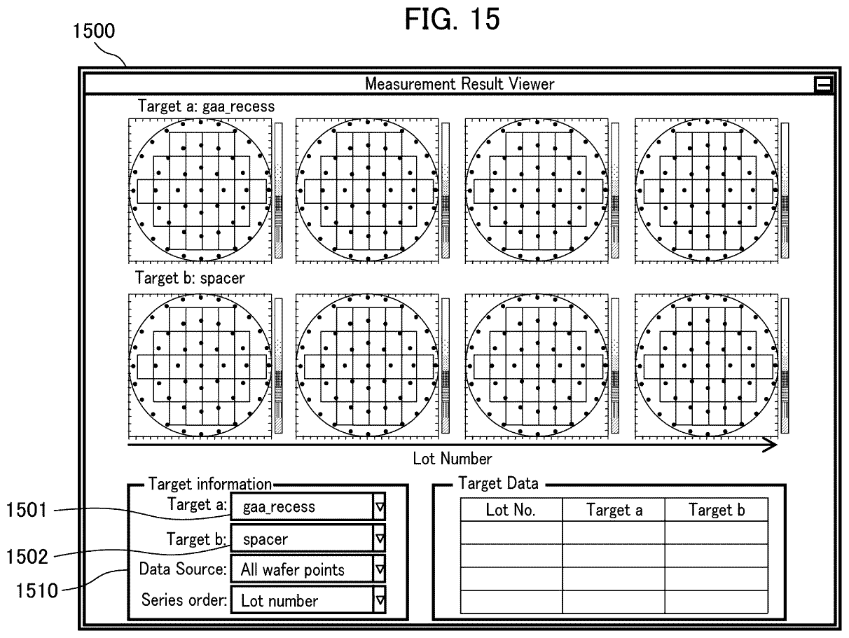

FIG. 15 is a drawing illustrating an example of a GUI screen chronologically displaying wafer maps of different measurement targets. Based on a measurement result outputted by the measurement apparatus 103, a processor built in the display apparatus 400 or the like generates such a GUI screen 1500 as shown in FIG. 15 as an example in accordance with a program stored in a storing medium.

FIG. 15 illustrates an example of an image showing chronological variation of a wafer map in which a lot number is taken as the horizontal axis. Further, the drawing illustrates an example of display in which chronological variation of different types of measurement targets is visualized by vertically disposing wafer maps of the different types of measurement targets. In the example in FIG. 15, at target setting fields 1501 and 1502 of an input area 1510, an amount of recess of a semiconductor device is selected as measurement target a (“Target a” in FIG. 15) and a width of a spacer of a semiconductor device (feature amount of another structure probably influencing an amount of recess is selected as measurement target b (“Target b” in FIG. 15).

By setting an amount of recess and a feature amount of another structure probably influencing an amount of recess as mentioned above, chronological correlation between an amount of recess and finish of another structure can be evaluated and it becomes possible to estimate an influence of recess of a structure produced in a manufacturing process different from a manufacturing process for producing recess on the recess. To compare in-plane distributions of three or more measurement targets, three or more target setting fields may be provided or distributions of a plurality of different types of measurement results may be displayed in a single wafer map in a superimposed manner.

### Effects of Embodiments

By performing the removal process S512 to S517 for removing the upper structure 611 to remove the upper structure 611, a feature amount of a lower structure (amount of recess of a SiGe layer) that cannot be directly observed or measured because of the upper structure 611 can be measured.

Since the upper structure 611 is removed by chemical reaction in the present embodiment, an influence on the Si/SiGe stacked layer 604 can be suppressed as compared with a method in which the upper structure 611 is removed by such a method that the upper structure 116 is physically processed by the FIB apparatus 111 or the like.

### Modification

The present invention is not limited to the above-described embodiments, and further includes various modifications. For example, the above-described embodiments have been described in detail in order to facilitate the understanding of the present invention, and the present invention is not necessarily limited to those including all of the described configurations. In addition, part of the configuration of one embodiment can be replaced with the configurations of other embodiments, and in addition, the configuration of the one embodiment can also be added with the configurations of other embodiments. In addition, part of the configuration of each of the embodiments can be subjected to addition, deletion, and replacement with respect to other configurations.

### List of Reference Signs

1: measurement system, 100: host computer, 101: network, 102: processing apparatus utilizing chemical reaction (semiconductor manufacturing apparatus), 103: measurement apparatus, 104: analysis system, 107: computer system, 108: film formation apparatus, 109: etching apparatus, 110: ashing apparatus, 111: FIB apparatus, 112: TEM, 201, 401: processor, 202, 402: main storage unit, 203, 403: auxiliary storage unit, 204, 404: input/output I/F, 301: electron source, 302: extraction electrode, 303: electron beam, 304: condenser lens, 305: scanning deflector, 306: objective lens, 307: sample chamber, 308: sample stage, 309: sample, 310: electron, 311: secondary electron, 312: conversion electrode, 313: detector, 314: control apparatus, 315: A/D converter, 316: image processing unit, 317: CPU, 318: image memory, 320: workstation, 400: display apparatus, 600: semiconductor device, 601: impurity region, 602: Si layer, 603: SiGe layer, 604: Si/SiGe stacked layer, 605: gate insulating film, 606: Poly-Si layer, 607: cap layer, 608: spacer, 609: SiOCN layer, 610: recess, 611: upper structure, 701: mask layer, 1200, 1300, 1400, 1500: GUI screen

1. A method for measuring a semiconductor device comprising:
preparing a semiconductor device having a first structure produced by a first manufacturing step and a second structure, provided below the first structure, produced by a second manufacturing step performed after the first manufacturing step;
removing the first structure of the semiconductor device by chemical reaction; and
applying a charged particle beam from above the semiconductor device with the first structure removed and using information obtained by irradiation with the charged particle beam to measure a feature amount of the second structure.

2. The method for measuring the semiconductor device according to claim 1,
wherein removing the first structure by chemical reaction includes:
depositing a mask layer so that a side face of the second structure is covered and a part of the first structure is exposed; and
removing the first structure exposed from the mask layer by chemical reaction; and
removing the mask layer.

3. The method for measuring the semiconductor device according to claim 2,
wherein the first structure includes a cap layer, and
wherein removing the first structure exposed from the mask layer by chemical reaction includes:
removing the cap layer of the first structure exposed from the mask layer by etching.

4. The method for measuring the semiconductor device according to claim 3,
wherein the first structure includes a polysilicon layer located below the cap layer, and
wherein removing the first structure exposed from the mask layer by chemical reaction includes:
after removing the cap layer, removing the polysilicon layer by etching.

5. The method for measuring the semiconductor device according to claim 4,
wherein the first structure includes a spacer that provides a side wall of the first structure, and
wherein removing the first structure exposed from the mask layer by chemical reaction includes:
after removing the cap layer and the polysilicon layer, removing the spacer by etching.

6. The method for measuring the semiconductor device according to claim 2,
wherein removing the mask layer includes:
removing the mask layer by ashing.

7. The method for measuring the semiconductor device according to claim 1,
wherein removing the first structure by chemical reaction includes:
removing the first structure of each semiconductor device by in-plane uniform chemical reaction to a wafer in which a plurality of the semiconductor devices is provided or a chip.

8. The method for measuring the semiconductor device according to claim 7, further comprising:
displaying a map image containing a measurement position on the wafer or the chip where a feature amount of the second structure has been measured and the feature amount in the measurement position.

9. The method for measuring the semiconductor device according to claim 8,
wherein displaying the map image includes:
displaying the map images of the different wafers or chips chronologically arranged.

10. The method for measuring the semiconductor device according to claim 1, further comprising:
before removing the first structure by chemical reaction, applying a charged particle beam from above the semiconductor device and using information obtained by irradiation with the charged particle beam to measure a feature amount of the first structure; and
comparing a feature amount of the first structure and a feature amount of the second structure with each other.

11. A system for measuring a semiconductor device comprising:
a processing apparatus that processes a semiconductor device having a first structure produced by a first manufacturing step and a second structure, provided below the first structure, produced by a second manufacturing step performed after the first manufacturing step and removes the first structure of the semiconductor device by chemical reaction; and
a measurement apparatus that applies a charged particle beam from above the semiconductor device with the first structure removed and uses information obtained by irradiation with the charged particle beam to measure a feature amount of the second structure.

12. The system for measuring the semiconductor device according to claim 11,
wherein the processing apparatus
deposits a mask layer so that a side face of the second structure is covered and a part of the first structure is exposed,
removes the first structure exposed from the mask layer by chemical reaction, and
removes the mask layer.

13. The system for measuring the semiconductor device according to claim 12,
wherein the first structure includes a cap layer, and
wherein the processing apparatus removes the cap layer of the first structure exposed from the mask layer by etching.

14. The system for measuring the semiconductor device according to claim 13,
wherein the first structure includes a polysilicon layer located below the cap layer, and
wherein the processing apparatus after the cap layer is removed, removes the polysilicon layer by etching.

15. The system for measuring the semiconductor device according to claim 14,
wherein the first structure includes a spacer that provides a side wall of the first structure, and
wherein the processing apparatus
after the cap layer and the polysilicon layer are removed, removes the spacer by etching.

16. The system for measuring the semiconductor device according to claim 15,
wherein the processing apparatus
after removing the first structure by chemical reaction, removes the mask layer by ashing.

17. The system for measuring the semiconductor device according to claim 11,
wherein the processing apparatus
removes the first structure of each semiconductor device by in-plane uniform chemical reaction to a wafer or a chip where a plurality of the semiconductor devices is provided.

18. The system for measuring the semiconductor device according to claim 11,
wherein the measurement apparatus
before the first structure is removed, applies a charged particle beam from above the semiconductor device and uses information obtained by irradiation with the charged particle beam to measure a feature amount of the first structure, and
compares a feature amount of the first structure and a feature amount of the second structure with each other.

19. A display apparatus capable of communicating with a measurement apparatus that measures a feature amount of a second structure of a semiconductor device having a first structure produced by a first manufacturing step and the second structure, provided below the first structure, produced by a second manufacturing step performed by the first manufacturing step and has the first structure removed by chemical reaction,
wherein the display apparatus displays a map image containing a measurement position on a wafer or a chip where the measurement apparatus has measured a feature amount of the second structure and the feature amount in the measurement position.

20. The display apparatus according to claim 19,
wherein the display apparatus
displays the map images of the different wafers or chips chronologically arranged.
